(19) United States
(12) Patent Application Publication
(10) Pub. No.: US 2021/0040645 A1
(43) Pub. Date: Feb. 11, 2021

(54) SILICON CARBIDE SINGLE CRYSTAL MANUFACTURING APPARATUS, AND MANUFACTURING METHOD OF SILICON CARBIDE SINGLE CRYSTAL

(71) Applicant: DENSO CORPORATION, Kariya-city (JP)

(72) Inventor: Nobuyuki OYA, Kariya-city (JP)

(21) Appl. No.: 17/081,058

(22) Filed: Oct. 27, 2020

Related U.S. Application Data
(63) Continuation of application No. PCT/JP2019/020444, filed on May 23, 2019.

(30) Foreign Application Priority Data
May 25, 2018 (JP) 2018-100904

(51) Int. Cl. C30B 35/00; C30B 29/36; C30B 25/10

(52) U.S. Cl. CPC C30B 35/002; C30B 25/10; C30B 29/36

(57) ABSTRACT

A silicon carbide single crystal manufacturing apparatus includes a crucible having a cylindrical shape and providing a hollow portion forming a reaction chamber, a pedestal disposed in the hollow portion of the crucible and having one circular surface on which a seed crystal for growing a silicon carbide single crystal is to be disposed, a gas supplying mechanism configured to supply a silicon carbide raw material gas for growing the silicon carbide single crystal on a surface of the seed crystal from below the pedestal, a heating device configured to heat and decompose the silicon carbide raw material gas, and a rotation mechanism configured to rotate the pedestal to cause the silicon carbide single crystal to grow while the seed crystal is rotated, and a center axis of the pedestal is eccentric from a rotation center of the pedestal.

### CROSS REFERENCE TO RELATED APPLICATIONS

The present application is a continuation application of International Patent Application No. PCT/JP2019/020444 filed on May 23, 2019, which designated the U.S. and claims the benefit of priority from Japanese Patent Application No. 2018-100904 filed on May 25, 2018. The entire disclosures of all of the above applications are incorporated herein by reference.

### TECHNICAL FIELD

The present disclosure relates to a silicon carbide (SiC) single crystal manufacturing apparatus and a manufacturing method of an SiC single crystal.

### BACKGROUND

Conventionally, there have been proposed an SiC single crystal manufacturing apparatus and a manufacturing method of an SiC single crystal by a gas growth method in which an SiC raw material gas is supplied to a growth plane of a seed crystal formed of an SiC single crystal and an SiC single crystal is grown on the seed crystal.

### SUMMARY

The present disclosure provides an SiC single crystal manufacturing apparatus and a manufacturing method of an SiC in which a center axis of a pedestal on which a seed crystal for growing an SiC single crystal is disposed is eccentric from a rotation center of the pedestal.

### BRIEF DESCRIPTION OF DRAWINGS

Objects, features and advantages of the present disclosure will become apparent from the following detailed description made with reference to the accompanying drawings. In the drawings:

FIG. 1 is a cross-sectional view of an SiC single crystal manufacturing apparatus according to a first embodiment;

FIG. 2 is a diagram showing a state in which a seed crystal is bonded to a pedestal;

FIG. 3 is a diagram showing a locus of a point A on a side where a facet plane is formed and a point B on the opposite side of the seed crystal;

FIG. 4 is a diagram showing a state in which an SiC single crystal is grown on a growth plane of a seed crystal;

FIG. 5 is a cross-sectional view of an SiC single crystal manufacturing apparatus according to a second embodiment; and

FIG. 6 is a cross-sectional view of an SiC single crystal manufacturing apparatus according to a third embodiment.

### DETAILED DESCRIPTION

An off-substrate whose growth plane is inclined at a predetermined off-angle from a (0001) C-plane may be used as a seed crystal, and an SiC single crystal may be grown by step-flow growth on a growth plane of the seed crystal. In order to relax a temperature distribution of a growth surface of the SiC single crystal, the SiC single crystal may be grown by rotating a pedestal to which the seed crystal is attached by a rotation mechanism.

When the SiC single crystal is grown, most of heterogeneous polymorphism and differently oriented crystal which become defects in the crystal growth are generated in a facet plane which is a plane coincident with the (0001) C-plane among the growth planes. As described above, when the SiC single crystal is grown on the seed crystal serving as the off-substrate, the facet plane is formed at a position biased to a part of an outer edge portion of the SiC single crystal, and the heterogeneous polymorphism and differently oriented crystal which cause the defect is generated at the position. Then, in the gas growth method, when the SiC single crystal is grown while the seed crystal is rotated together with the pedestal, since distances between the pedestal and the seed crystal, and a cylindrical heating vessel surrounding the pedestal and the seed crystal are uniform, the facet plane is formed at a position close to the wall surface of the heating vessel.

Ideally, a wall surface of the heating vessel is at a uniform temperature around the growth surface of the SiC single crystal, but in practice there is a temperature variation. In addition, although it is ideal that the SiC raw material gas supplied from the gas supply port is supplied uniformly, i.e., rotationally symmetrically, with respect to the center of the growth plane of the SiC single crystal without variation, actually, there is a supply variation. In particular, a flow direction of the SiC raw material gas fluctuates depending on the placement position of a gas exhaust port provided above the pedestal, and the supply of the SiC raw material gas is not uniformly performed. As described above, the variation factors of the growth conditions, such as the temperature variation of the wall surface of the heating vessel and the variation of the gas flow, are large, and the probability of occurrence of the heterogeneous polymorphism or the differently oriented crystal on the facet plane is high.

A silicon carbide single crystal manufacturing apparatus according one aspect of the present disclosure includes a crucible having a cylindrical shape and providing a hollow portion forming a reaction chamber, a pedestal disposed in the hollow portion of the crucible and having one surface on which a seed crystal for growing a silicon carbide single crystal is to be disposed, the one surface of the pedestal having a circular shape, a gas supplying mechanism configured to supply a silicon carbide raw material gas for growing the silicon carbide single crystal on a surface of the seed crystal from below the pedestal, a heating device configured to heat and decompose the silicon carbide raw material gas, and a rotation mechanism configured to rotate the pedestal to cause the silicon carbide single crystal to grow while the seed crystal is rotated, and a center axis of the pedestal is eccentric from a rotation center of the pedestal.

In this manner, the center axis of the pedestal is made to be eccentric from the rotation center of the pedestal. For that reason, when the silicon carbide single crystal is grown by placing the point of the seed crystal at which the downstream side in the off-direction is located on the side closest to the rotation center of the pedestal, the side of the SiC single crystal on which the facet plane is formed is separated from the inner wall surface of the crucible. Therefore, the influence of the temperature variation of the wall surface of the crucible can be reduced, and the influence of the variation of the gas flow can also be reduced. For that reason, the probability of occurrence of heterogeneous polymorphism or differently oriented crystal in the facet plane of the silicon carbide single crystal can be reduced.

Further, a manufacturing method of a silicon carbide single crystal according to another aspect of the present disclosure includes: disposing a pedestal in a crucible having a cylindrical shape and providing a hollow portion forming a reaction chamber, the pedestal having one surface on which a seed crystal for growing the silicon carbide single crystal is disposed, the one surface having a circular shape; and growing the silicon carbide single crystal on a surface of the seed crystal while the seed crystal is rotated by supplying a thermally decomposed silicon carbide raw material gas from below the pedestal, and rotating the pedestal. In the growing of the silicon carbide single crystal, a center axes of the pedestal and the seed crystal are eccentric from a rotation center of the pedestal. In the disposing of the pedestal, an off-substrate whose surface has a predetermined off-angle with respect to a (0001) C-plane is used as the seed crystal, and the pedestal on which the seed crystal is disposed in such a manner that a portion of the seed crystal on a downstream side in an off-direction is located closer to the rotation center than a portion of the seed crystal on an upstream side in the off-direction is disposed in the crucible. With the manufacturing method described above, the side of the silicon carbide single crystal on which the facet plane is formed is separated from the inner wall surface of the crucible. Therefore, the influence of the temperature variation of the wall surface of the crucible can be reduced, and the influence of the variation of the gas flow can also be reduced. For that reason, the probability of occurrence of heterogeneous polymorphism or differently oriented crystal in the facet plane of the silicon carbide single crystal can be reduced.

Embodiments of the present disclosure will be described below with reference to the drawings. In the following embodiments, the same reference numerals are assigned to parts that are the same as or equivalent to each other for description.

### First Embodiment

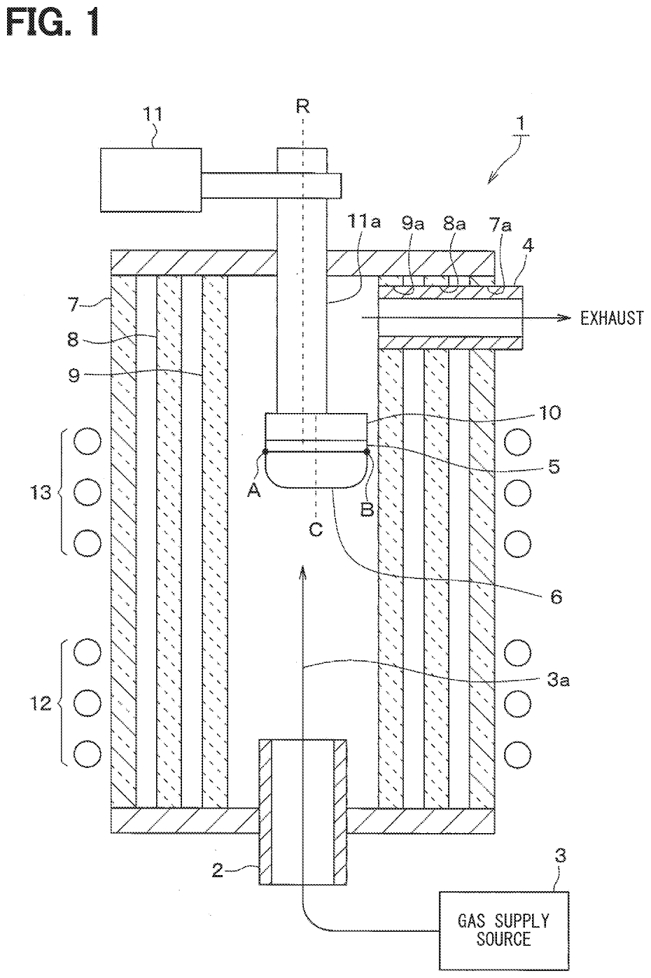

An SiC single crystal manufacturing apparatus 1 shown in FIG. 1 is used for manufacturing an SiC single crystal ingot by long growth, and is placed so that a vertical direction of a paper plane of FIG. 1 faces a vertical direction.

Specifically, the SiC single crystal manufacturing apparatus 1 causes a supply gas 3a containing an SiC raw material gas from a gas supply source 3 to flow in through a gas supply port 2, and causes an unreacted gas to be exhausted through a gas exhaust port 4, thereby growing an SiC single crystal 6 on a seed crystal 5 formed of an SiC single crystal substrate.

The SiC single crystal manufacturing apparatus 1 includes the gas supply source 3, a vacuum container 7, a heat insulating material 8, a heating vessel 9, a pedestal 10, a rotary pulling mechanism 11, and first and second heating devices 12 and 13.

The gas supply source 3 supplies an SiC raw material gas containing Si and C together with a carrier gas, for example, a mixed gas of a silane-based gas such as silane and a hydrocarbon-based gas such as propane, from the gas supply port 2. The gas supply source 3 and the like configure a gas supply mechanism for supplying the SiC raw material gas to the seed crystal 5 from below.

The vacuum container 7 is made of quartz glass or the like, has a cylindrical shape having a hollow portion, in the present embodiment, a cylindrical shape, and is structured so that the supply gas 3a can be introduced and led out. The vacuum container 7 accommodates other components of the SiC single crystal manufacturing apparatus 1, and is configured to be able to reduce a pressure by drawing a pressure in an accommodated internal space. gas supply port 2 of a supply gas 3a is provided at a bottom of the vacuum container 7, a through hole 7a is provided at a top, specifically, at a position above a side wall of the vacuum container 7, and a gas exhaust port 4 of an exhaust gas such as an unreacted gas of the supply gas 3a is fitted into the through hole 7a.

The heat insulating material 8 has a cylindrical shape having a hollow portion, in the present embodiment, a cylindrical shape, and is disposed coaxially with the vacuum container 7. The heat insulating material 8 has a cylindrical shape having a diameter smaller than that of the vacuum container 7, and is disposed inside the vacuum container 7, thereby inhibiting a heat transfer from a space inside the heat insulating material 8 to the vacuum container 7. The heat insulating material 8 is made of, for example, graphite alone or graphite whose surface is coated with a high-melting point metal carbide such as TaC (tantalum carbide) or NbC (niobium carbide), and is hardly subjected to thermal etching.

The heating vessel 9 configures a crucible serving as a reaction vessel, and has a cylindrical shape having a hollow portion, in the present embodiment, a cylindrical shape. The hollow portion of the heating vessel 9 configures a reaction chamber in which the SiC single crystal 6 is grown on a surface of the seed crystal 5. The heating vessel 9 is made of, for example, graphite alone or graphite whose surface is coated with a high-melting point metal carbide such as TaC or NbC, and is hardly subjected to thermal etching. The heating vessel 9 is disposed so as to surround the pedestal 10. An exhaust gas such as an unreacted gas in the supply gas 3a is guided to the gas exhaust port 4 through a space between an inner peripheral surface of the heating vessel 9 and outer peripheral surfaces of the seed crystal 5 and the pedestal 10. The SiC raw material gas in the supply gas 3a is decomposed by the heating vessel 9 until the supply gas 3a from the gas supply port 2 is guided to the seed crystal 5.

A through hole is provided in an upper portion of the heat insulating material 8 and the heating vessel 9, specifically, at a position above the side wall, and the gas exhaust port 4 is fitted into the through hole, whereby the exhaust gas can be exhausted from the inside of the heating vessel 9 to the outside of the vacuum container 7.

The pedestal 10 is a member for placing the seed crystal 5. One surface of the pedestal 10 on which the seed crystal 5 is placed has a circular shape, and the pedestal 10 is disposed at a position in which a center axis of the pedestal 10 is eccentric with respect to a center axis of the heating vessel 9 and a center axis of a shaft 11a of the rotary pulling mechanism 11, which will be described later. The pedestal 10 is made of, for example, graphite alone or graphite whose surface is coated with a high-melting point metal carbide such as TaC or NbC, and is hardly subjected to thermal etching. The seed crystal 5 is attached to one surface of the pedestal 10 on the gas supply port 2 side, and the SiC single crystal 6 is grown on the surface of the seed crystal 5. The surface of the pedestal 10 to which the seed crystal 5 is attached has a shape corresponding to the shape of the seed crystal 5, and in the present embodiment, the pedestal 10 is formed of a cylindrical member having the same diameter as that of the seed crystal 5, so that one surface on which the seed crystal 5 is placed has a circular shape. Further, the pedestal 10 is connected to the shaft 11a in a surface opposite to a surface of the seed crystal 5 is placed, is rotated with the rotation of the shaft 11a, and can be pulled upward of the paper plane while the shaft 11a is pulled up.

A distance between the center axis of the pedestal 10 and the center axis of the heating vessel 9 is arbitrary, and may be appropriately set according to a diameter of the pedestal 10. However, when the center axis of the pedestal 10 is eccentric from the center axis of the heating vessel 9, a part of the outer periphery of the pedestal 10 approaches the inner wall surface of the heating vessel 9. In consideration of the above configuration, it is preferable that the distance between the pedestal 10 and the heating vessel 9 is set to 20 mm or more at a position where the distance between the pedestal 10 and the inner wall surface of the heating vessel 9 is shortest. With the above configuration, an influence of a temperature of the heating vessel 9 on the SiC single crystal 6 can be reduced, and polycrystallization of the SiC single crystal 6 can be inhibited.

The rotary pulling mechanism 11 rotates and pulls up the pedestal 10 through the shaft 11a formed of a pipe member or the like. In the present embodiment, the shaft 11a is formed in a straight line extending up and down, and one end of the shaft 11a is connected to a surface of the pedestal 10 opposite to an attachment surface of the seed crystal 5, and the other end of the shaft 11a is connected to a main body of the rotary pulling mechanism 11. The shaft 11a is also made of, for example, graphite alone or graphite whose surface is coated with a high-melting point metal carbide such as TaC or NbC, and is hardly subjected to thermal etching. With the above configuration, the pedestal 10, the seed crystal 5, and the SiC single crystal 6 can be rotated and pulled up, so that a growth plane of the SiC single crystal 6 can have a desired temperature distribution, and a temperature of the growth surface can be adjusted to a temperature suitable for growth along with the growth of the SiC single crystal 6.

The first and second heating devices 12 and 13 are formed of a heating coil such as an induction heating coil or a direct heating coil, and are disposed so as to surround a periphery of the vacuum container 7. In the case of the present embodiment, the first and second heating devices 12 and 13 are configured by induction heating coils. The first and second heating devices 12 and 13 are configured to be able to independently control the temperature of a target location, the first heating device 12 is disposed at a position corresponding to a lower position of the heating vessel 9, and the second heating device 13 is disposed at a position corresponding to the pedestal 10. Therefore, the temperature of the lower portion of the heating vessel 9 can be controlled by the first heating device 12 to heat and decompose the SiC raw material gas. In addition, the temperature around the pedestal 10, the seed crystal 5, and the SiC single crystal 6 can be controlled to a temperature suitable for the growth of the SiC single crystal 6 by the second heating device 13.

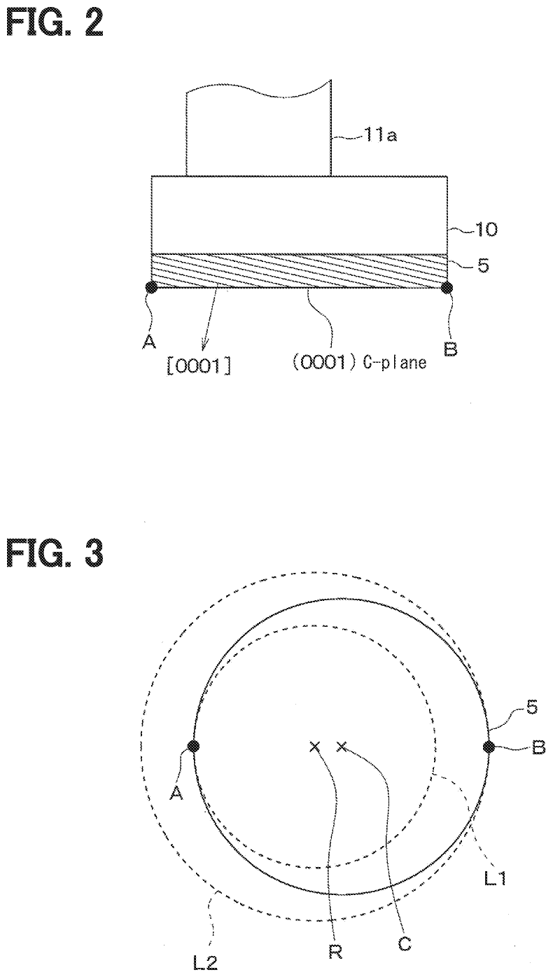

In this manner, the SiC single crystal manufacturing apparatus 1 according to the present embodiment is configured. Next, a method of manufacturing the SiC single crystal 6 using the SiC single crystal manufacturing apparatus 1 according to the present embodiment will be described with reference to FIGS. 2 to 4 in addition to FIG. 1.

First, the seed crystal 5 is attached to one surface of the pedestal 10. As shown in FIG. 2, the seed crystal 5 is an off-substrate whose one surface on the opposite side to the pedestal 10, that is, the growth plane of the SiC single crystal 6 has a predetermined off-angle of, for example, 4° or 8° with respect to the (0001) C-plane. In the seed crystal 5, when a portion downstream of an off-direction of the seed crystal 5 is defined as a point A, and the opposite side is defined as a point B, the seed crystal 5 is attached to the pedestal 10 so that the point A is placed at a portion of an outer periphery of the pedestal 10 at a side closest to the center axis of the shaft 11a, the point B is placed at a portion farthest from the center axis. In other words, the seed crystal 5 is placed on the pedestal 10 so that the portion of the seed crystal 5 on which the downstream side in the off-direction is located is closer to the rotation center side than the opposite side. Incidentally, the off-direction refers to “a direction parallel to a vector obtained by projecting a normal vector of the growth plane, in the present embodiment, a normal vector to the (0001) C-plane, that is, a vector of <0001> direction onto the surface of the seed crystal 5”. The downstream side in the off-direction defines one of the two sides, and means “the side where a tip of the vector obtained by projecting the normal vector of the growth plane onto the surface of the seed crystal 5 faces”.

Subsequently, the pedestal 10 and the seed crystal 5 are placed in the heating vessel 9. Then, the first and second heating devices 12 and 13 are controlled to provide a desired temperature distribution. In other words, in the temperature distribution, the SiC raw material gas contained in the supply gas 3a is heated and decomposed to be supplied to the surface of the seed crystal 5, and the SiC raw material gas is recrystallized on the surface of the seed crystal 5, while a sublimation rate is higher than a recrystallization rate in the heating vessel 9. With the above configuration, for example, a temperature of the bottom of the heating vessel 9 can be set to about 2400° C., and a temperature of the surface of the seed crystal 5 can be set to about 2200° C.

In addition, a supply gas 3a containing an SiC raw material gas is introduced through the gas supply port 2 while introducing a carrier gas using an inert gas such as Ar or He or an etching gas such as H₂ or HCl as required while the vacuum container 7 is kept at a desired pressure. As a result, the supply gas 3a flows as indicated by an arrow in FIG. 1 and is supplied to the seed crystal 5, and the SiC single crystal 6 is grown on the surface of the seed crystal 5 based on the gas supply.

Then, the rotary pulling mechanism 11, while rotating the pedestal 10 and seed crystals 5 and SiC single crystal 6 through the shaft 11a, pulled in accordance with the growth rate of the SiC single crystal 6. As a result, a height of the growth surface of the SiC single crystal 6 is kept substantially constant, and a temperature distribution of the growth surface temperature can be controlled with high controllability. In addition, since the SiC single crystal 6 is grown in the high-temperature heating vessel 9, the crystal can be prevented from adhering to the surface other than the seed crystal 5, and clogging of the gas exhaust port 4 can be prevented so that the SiC single crystal 6 can continuously grow.

In this example, as described above, the center axis of the pedestal 10 is eccentric with respect to the center axis of the shaft 11a, and the seed crystal 5 is attached to the pedestal 10. For that reason, as shown in FIG. 3, when the pedestal 10 is rotated by the rotary pulling mechanism 11, the center C of the seed crystal 5 moves so as to revolve with respect to the center axis of the shaft 11a, which is a rotation center R of the seed crystal 5 and the pedestal 10, and a locus L1 of the point A enters the inside of the locus L2 of the point B. In other words, the point A has a locus that moves in the vicinity of the rotation center R of rotation of the seed crystal 5 or the pedestal 10, as compared with the case where the center axis of the pedestal 10 is not eccentric with respect to the center axis of the shaft 11a. In the following description, the rotation center R of the seed crystal 5 and the pedestal 10 is simply referred to as a rotation center R.

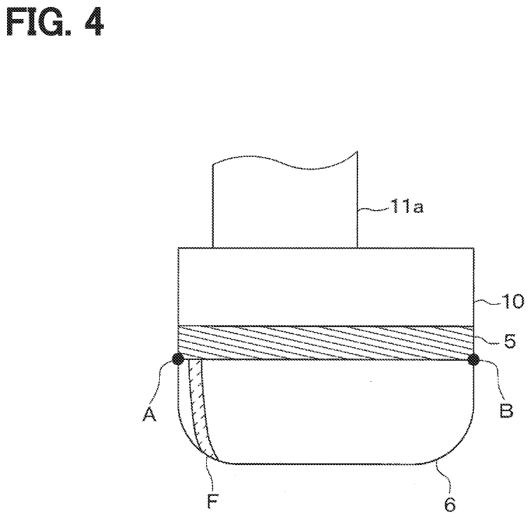

As shown in FIG. 4, when the SiC single crystal 6 is grown on the growth plane of the seed crystal 5, a facet plane F coinciding with the (0001) C-plane is formed on the position of the point A. In the point A, as compared with the case where the center axis of the pedestal 10 is not eccentric with respect to the center axis of the shaft 11a as described above, since a locus that moves in the vicinity of the rotation center R is drawn, the distance from the inner wall surface of the heating vessel 9 can be separated.

For that reason, in the vicinity of the point A where the facet plane F is formed, the influence of the temperature variation of the wall surface of the heating vessel 9 is reduced. In addition, since the center of the SiC single crystal 6 is rotated in a state of being eccentric with respect to the center axis of the shaft 11a, the influence of the variation of the gas flow on the facet plane F is reduced as compared with the case in which the center of the SiC single crystal 6 is rotated in a state of being coincident with the center axis of the shaft 11a. In other words, the facet plane F moves at a position away from the wall surface of the heating vessel 9, and even if there is a variation in the gas flow in the vicinity of the wall surface of the heating vessel 9, the influence of the variation in the gas flow is consequently reduced. In addition, a gap between the pedestal 10 and the heating vessel 9 in the vicinity of the point A where the facet plane F is formed is widened, thereby alleviating the influence of the variation in the gas flow. Further, since the diameter of the pedestal 10 is adjusted to the diameter of the SiC single crystal 6, the gap between the pedestal 10 and the heating vessel 9 is also changed with the rotation of the pedestal 10. For that reason, the gas flow can be changed accordingly, and the variation of the gas flow can be reduced on average as compared with the case in which a variation occurs as the same gas flow is maintained.

As described above, in the SiC single crystal manufacturing apparatus 1 according to the present embodiment, the center axis of the pedestal 10 is eccentric with respect to the center axis of the shaft 11a so that the centers of the growth planes of the seed crystal 5 and the SiC single crystal 6 are eccentric from the rotation center R. The point A of the seed crystal 5 at which the downstream side in the off-direction is located is placed at a position closest to the center axis of the shaft 11a of the pedestal 10.

As a result, the point A side where the facet plane F is formed on the SiC single crystal 6 can be separated from the inner wall surface of the heating vessel 9, and the influence of the temperature variation of the wall surface of the heating vessel 9 can be reduced, and the influence of the variation of the gas flow can also be reduced. This makes it possible to reduce the probability of occurrence of heterogeneous polymorphism or differently oriented crystal in the facet plane F of the SiC single crystal 6.

### Second Embodiment

A second embodiment will be described. In the present embodiment, the structure in which the center axis of the pedestal 10 is eccentric from the rotation center R is changed from that in the first embodiment, and the other configuration is the same as that in the first embodiment, and therefore, only portions different from those in the first embodiment will be described.

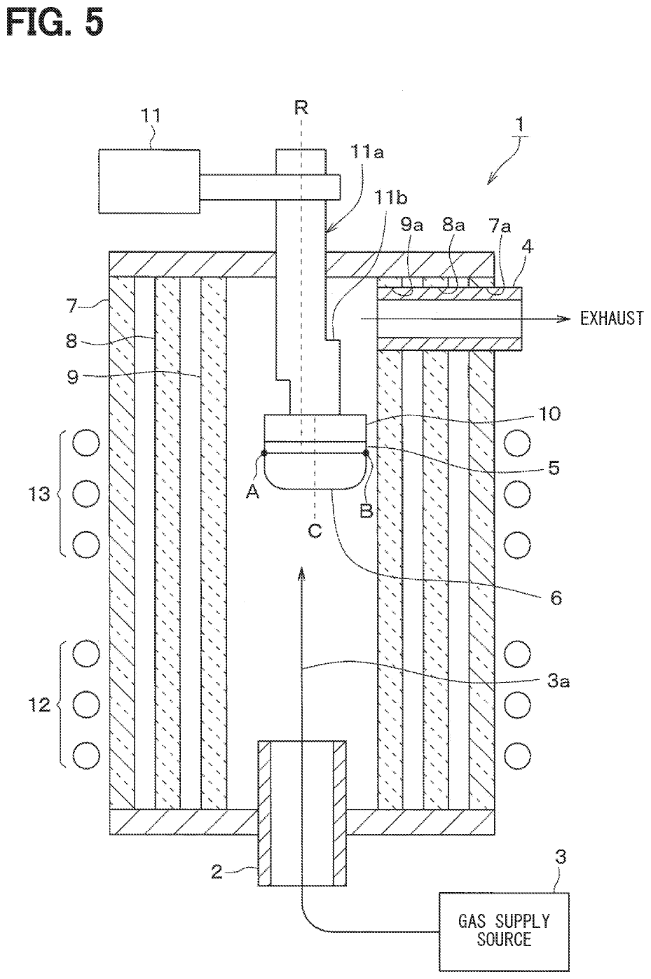

As shown in FIG. 5, in the present embodiment, the entire shaft 11a is not straight, but has a bent portion 11b. The bent portion 11b is configured such that a shaft 11a is bent at an intermediate position of the shaft 11a, that is, between an upper surface of a vacuum container 7 and a pedestal 10. Specifically, the bent portion 11b is formed at a position away from the upper surface of the vacuum container 7 in a state in which the pedestal 10 is positioned at a lowest position. The position at which the bent portion 11b is formed is determined by a rotary pulling mechanism 11 so that the bent portion 11b does not come into contact with the upper surface of the vacuum container 7 even when the pedestal 10 is pulled up together with the shaft 11a.

The pedestal 10 is fixed to the shaft 11a so that the center axis of the pedestal 10 coincides with the center axis of a portion of the shaft 11a located below the bent portion 11b.

In the case of the configuration described above, the center axis of the portion of the shaft 11a located above the bent portion 11b is a rotation center R. For that reason, a portion of the shaft 11a lower than the bent portion 11b, that is, a portion to which the pedestal 10 is attached, is eccentric with respect to the rotation center R, and the center axis of the pedestal 10 is also eccentric with respect to the rotation center R. Therefore, the same effects as those of the first embodiment can be obtained also in the structure of the present embodiment.

### Third Embodiment

A third embodiment will be described. The present embodiment is also modified from the first embodiment in the structure in which a center axis of a pedestal 10 is eccentric from a rotation center R, and other configuration is the same as that of the first embodiment, and therefore only portions different from those of the first embodiment will be described.

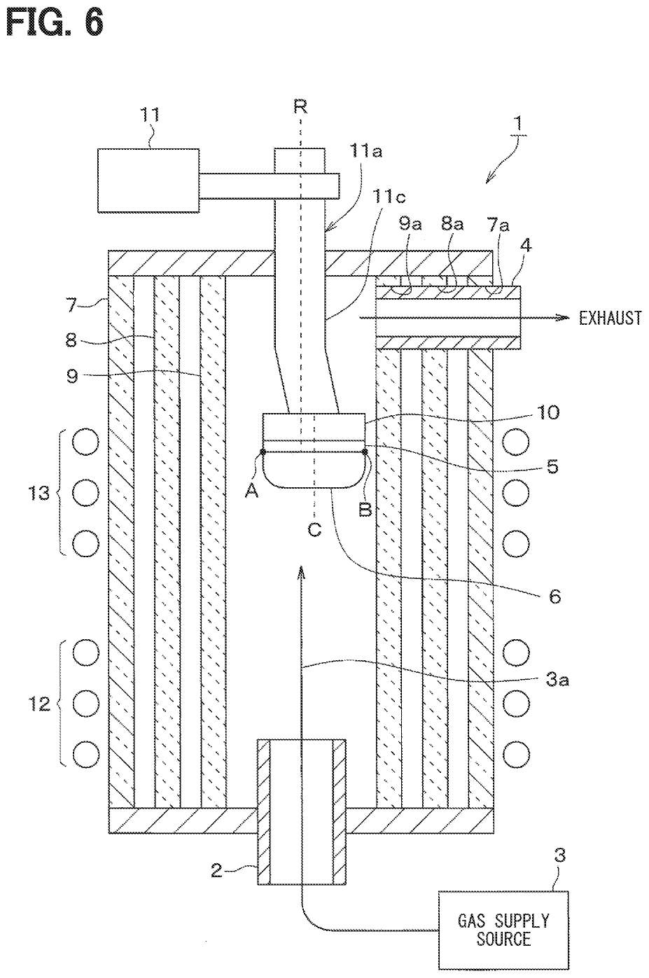

As shown in FIG. 6, in the present embodiment, the entire shafts 11a is not straight, but is bent at an intermediate position of the shafts 11a, that is, between an upper surface of a vacuum container 7 and a pedestal 10, so that an inclined portion 11c inclined with respect to the center axis of a heating vessel 9 are provided. Specifically, the inclined portion 11c is formed at a position away from an upper surface of the vacuum container 7 in a state in which the pedestal 10 is positioned at the lowest position. A position at which the inclined portion 11c is formed is determined by a rotary pulling mechanism 11 so that the inclined portion 11c does not come into contact with the upper surface of the vacuum container 7 even when the pedestal 10 is pulled up together with the shaft 11a. The center of the lower end of the inclined portion 11c to which the pedestal 10 is attached is eccentric from a rotation center R.

On the other hand, the pedestal 10 is fixed to the shaft 11a such that the center axis of the pedestal 10 coincides with the center of a lower end of the inclined portion 11c of the shaft 11a.

In the case of the configuration described above, the center axis of a portion of the shaft 11a located above the inclined portion 11c is the rotation center R. For that reason, the center axis of the pedestal 10 is eccentric with respect to the rotation center R. Therefore, the same effects as those of the first embodiment can be obtained also in the structure of the present embodiment.

### Other Embodiments

Although the present disclosure has been described in accordance with the above-described embodiments, the present disclosure is not limited to the above-described embodiments, and encompasses various modifications and variations within the scope of equivalents. In addition, various combinations and configurations, as well as other combinations and configurations that include only one element, more, or less, are within the scope and spirit of the present disclosure.

For example, in each of the embodiments described above, the center axis of the pedestal 10 is eccentric from the rotation center R so that the center of the seed crystal 5 is eccentric from the rotation center R. However, the above configuration is also merely an example, and the center of the seed crystal 5 may be eccentric from the rotation center R by other configurations. For example, while the center axis of the pedestal 10 coincides with the rotation center R, the diameter of the pedestal 10 is set to be larger than the diameter of the seed crystal 5, and the seed crystal 5 is attached to the pedestal 10 so that the center of the seed crystal 5 is deviated from the center of the pedestal 10. Even in this manner, the center of the seed crystal 5 can be eccentric from the rotation center R. However, in the case of the structure described above, there is a portion around the seed crystal 5 where nothing is attached to the surface of the pedestal 10, and there is a possibility that polycrystal grows on the surface and adheres to the SiC single crystal 6, which has an adverse effect. For that reason, it is preferable to make the diameter of the pedestal 10 coincide with the diameter of the seed crystal 5 as in the embodiments described above.

Further, although the rotary pulling mechanism 11 capable of both rotating and pulling up the pedestal 10 has been exemplified, a rotation mechanism capable of rotating at least the pedestal 10 may be used.

In the embodiments described above, the SiC single crystal manufacturing apparatus 1 has been described as an example of an up-flow method in which the supply gas 3a is supplied to the growth surface of the SiC single crystal 6 and then passed through the outer peripheral surface of the SiC single crystal 6 or the side of the pedestal 10 to be further exhausted upward. However, the present disclosure is not limited to the above configuration, but a return flow system may be applied in which after the supply gas 3a is supplied to the growth surface of the SiC single crystal 6, the supply gas 3a is returned in the same direction as the supply direction again. In addition, a side-flow method may be employed in which the supply gas 3a is supplied to the growth surface of the SiC single crystal 6 and then exhausted toward the outer periphery of the heating vessel 9.

What is claimed is:

1. A silicon carbide single crystal manufacturing apparatus comprising:
a crucible having a cylindrical shape and providing a hollow portion forming a reaction chamber;
a pedestal disposed in the hollow portion of the crucible and having one surface on which a seed crystal for growing a silicon carbide single crystal is to be disposed, the one surface of the pedestal having a circular shape;
a gas supplying mechanism configured to supply a silicon carbide raw material gas for growing the silicon carbide single crystal on a surface of the seed crystal from below the pedestal;
a heating device configured to heat and decompose the silicon carbide raw material gas; and
a rotation mechanism configured to rotate the pedestal to cause the silicon carbide single crystal to grow while the seed crystal is rotated, wherein
a center axis of the pedestal is eccentric from a rotation center of the pedestal.

2. The silicon carbide single crystal manufacturing apparatus according to claim 1, wherein
the rotation mechanism includes a shaft configured to rotate the pedestal, and
the shaft is straight and a center of the pedestal is eccentric from a center axis of the shaft.

3. The silicon carbide single crystal manufacturing apparatus according to claim 1, wherein
the rotation mechanism includes a shaft configured to rotate the pedestal, and
the shaft has a bent portion to cause a lower portion of the shaft to which the pedestal is attached to be eccentric from the rotation center, and a center axis of the pedestal is coincident with a center axis of the lower portion of the shaft.

4. The silicon carbide single crystal manufacturing apparatus according to claim 1, wherein
the rotation mechanism includes a shaft configured to rotate the pedestal,
the shaft has an inclined portion inclined with respect to a rotation axis of the shaft, and a lower end of the inclined portion is eccentric from the rotation center, and
a center axis of the pedestal is coincident with a center of the lower end of the shaft.

5. A manufacturing method of a silicon carbide single crystal, comprising:
disposing a pedestal in a crucible having cylindrical shape and providing a hollow portion forming a reaction chamber, the pedestal having one surface on which a seed crystal for growing the silicon carbide single crystal is disposed, the one surface having a circular shape; and
growing the silicon carbide single crystal on a surface of the seed crystal while the seed crystal is rotated by supplying a thermally decomposed silicon carbide raw material gas from below the pedestal, and rotating the pedestal, wherein
in the growing of the silicon carbide single crystal, a center axes of the pedestal and the seed crystal are eccentric from a rotation center of the pedestal, and
in the disposing of the pedestal, an off-substrate whose surface has a predetermined off-angle with respect to a (0001) C-plane is used as the seed crystal, and the pedestal on which the seed crystal is disposed in such a manner that a portion of the seed crystal on a downstream side in an off-direction is located closer to the rotation center than a portion of the seed crystal on an upstream side in the off-direction is disposed in the crucible.
